(19) United States
(12) Patent Application Publication
(10) Pub. No.: US 2021/0140044 A1
(43) Pub. Date: May 13, 2021

(54) FILM FORMING METHOD AND FILM FORMING APPARATUS

(71) Applicant: Tokyo Electron Limited, Tokyo (JP)

(72) Inventors: Hiroshi Nagaike, Kurokawa-gun, Miyagi (JP); Daisuke Yoshikoshi, Kurokawa-gun, Miyagi (JP); Takao Funakubo, Kurokawa-gun, Miyagi (JP); Takahisa Iwasaki, Hillsboro, OR (US); Chiju Hsieh, Kurokawa-gun, Miyagi (JP); Yuki Azuma, Kurokawa-gun, Miyagi (JP)

(21) Appl. No.: 16/977,162

(22) PCT Filed: Jul. 23, 2019
(86) PCT No.: PCT/JP2019/028805

§ 371 Date: Sep. 1, 2020

(30) Foreign Application Priority Data
Jul. 27, 2018 (JP) 2018-141402

(51) Int. Cl. C23C 16/455; C23C 16/505; H01L 21/02; H01L 21/311; C23C 16/52; C23C 16/40

(52) U.S. Cl. CPC C23C 16/45536; C23C 16/505; H01L 21/02274; C23C 16/45544; H01L 21/31116; C23C 16/52; C23C 16/401; H01L 21/0228

(57) ABSTRACT

A film forming method of forming a predetermined film on a substrate by PEALD includes: adsorbing a precursor on the substrate; and forming plasma from a modifying gas and modifying the precursor adsorbed on the substrate with radicals contained in the plasma. Here, the modifying of the precursor includes supplying a radio frequency power having an effective power smaller than 500 W to a plasma source configured to form the plasma from the modifying gas.

### TECHNICAL FIELD

The various aspects and embodiments described herein pertain generally to a film forming method and a film forming apparatus.

### BACKGROUND

Patent Document 1 discloses a method for forming an oxide film on a substrate by plasma-enhanced atomic layer deposition (PEALD). In this film forming method, an oxide film, such as a silicon oxide film, is formed by the PEALD by repeating a cycle including following processes (i) and (ii). The process (i) includes supplying a precursor to a reaction space where a substrate is placed, for example, to adsorb the precursor on the substrate and purging to remove a non-adsorbed precursor from the substrate. The process (ii) includes exposing the adsorbed precursor to plasma, such as oxygen, to cause surface reaction to the adsorbed precursor and purging to remove a non-reacted component from the substrate.

### PRIOR ART DOCUMENT

Patent Document 1: Japanese Patent Laid-open Publication No. 2015-061075

### DISCLOSURE OF THE INVENTION

### Problems to be Solved by the Invention

The technology disclosed herein can improve a productivity when a film is formed by PEALD.

### Means for Solving the Problems

In one exemplary embodiment, a film forming method of forming a predetermined film on a substrate by PEALD includes: adsorbing a precursor on the substrate; and forming plasma from a modifying gas and modifying the precursor adsorbed on the substrate with radicals contained in the plasma. Here, the modifying of the precursor includes supplying a radio frequency power having an effective power smaller than 500 W to a plasma source configured to form the plasma from the modifying gas.

### Effect of the Invention

According to the present disclosure, it is possible to improve the productivity when the film is formed by the PEALD.

### BRIEF DESCRIPTION OF THE DRAWINGS

FIG. 1 is a longitudinal cross-sectional view schematically illustrating a configuration of a plasma processing apparatus as a film forming apparatus according to a first exemplary embodiment.

FIG. 2 is a flowchart provided to explain a processing on a wafer W in the plasma processing apparatus illustrated in FIG. 1.

FIG. 3 shows an attachment position of a test piece in an experiment conducted by the present inventors.

FIG. 4 shows the result of an evaluation test 1.

FIG. 5 shows the result of an evaluation test 2.

### DETAILED DESCRIPTION

First, a conventional film forming method disclosed in Patent Document 1 will be described.

In a manufacturing process of a semiconductor device, a processing such as film forming processing is performed on a target substrate (hereinafter, referred to as “substrate”) such as a semiconductor wafer. A film forming method may be, for example, ALD, and a film forming apparatus repeats a predetermined cycle to deposit atomic layers one by one and thus forms a desired film on the substrate.

In the method for forming the oxide film on the substrate by the PEALD according to Patent Document 1, the cycle including the following processes (i) and (ii) is repeated as described above. In the process (i), the precursor is supplied to the reaction space to adsorb the precursor on the substrate and then, the purging is performed to remove the non-adsorbed precursor from the substrate. In the process (ii), the adsorbed precursor is exposed to the plasma to cause the surface reaction to the adsorbed precursor and then, the purging is performed to remove the non-reacted component from the substrate.

Herein, even if radicals (oxygen radicals or the like) contained in the plasma that causes the surface reaction to the precursor during film formation are excessively supplied near the substrate, they do not have a bad influence on the film formation. Excess radicals simply do not contribute to modification (reaction) of an adsorption layer formed of the precursor. Therefore, during the film formation, a sufficient amount of radicals is supplied near the substrate such that the precursor on the entire surface of the substrate can be modified by being reacted with the radicals. Thus, it is possible to secure the stability of the film formation such as film thickness uniformity.

The radicals that do not contribute to the modification on the surface of the substrate reach other places, such as an inner wall of a processing container where the substrate is accommodated, than the substrate. As a result, if the precursor exists in the places where the radicals reach, the radicals react with the precursor to generate an unnecessary reaction product (hereinafter, referred to as “deposit”). The generated deposit can be removed by dry cleaning with plasma or the like. However, radicals, such as oxygen (O) radicals, have long lifetime, and radicals that do not react with the substrate may generate the deposit in a place where it is difficult to remove the deposit by the dry cleaning (for example, a portion which is several 10 cm to several m apart from the substrate and placed at an exhaust-direction downstream side than the processing container).

Methods for removing the deposit include dry cleaning with a nitrogen trifluoride (NF₃) gas and the like or cleaning with remote plasma. However, it requires a long time to remove the deposit generated in the place, such as the portion at the exhaust-direction downstream side than the processing container, far from the region where plasma is formed. Further, if it is technically difficult to perform these cleaning processes, a portion to which the deposit adheres may be removed and then, cleaning with a chemical solution and the like may be performed. However, even in this case, it requires a long time to remove the deposit.

In addition to the above-described methods for removing the deposit, there is a method of suppressing the adhesion of the deposit by controlling a temperature only. For example, there is a method in which a portion where the adhesion of the deposit is suppressed has a higher temperature than a substrate serving as the film forming target because the deposit is generally likely to adhere to a low-temperature portion. For example, if the substrate is set to 2020 C. and an inner wall of the apparatus is set to 6020 C., the amount of deposit adhering to the inner wall of the apparatus can be reduced. However, the film formation by the ALD progresses as the temperature of the substrate increases. For this reason, in many cases, when the film formation is performed by the ALD, it is difficult to set the portion where the adhesion of the deposit is to be suppressed to a higher temperature than the substrate serving as the film forming target.

Hereinafter, a film forming apparatus and a film forming method according to the present exemplary embodiment for reducing the amount of the reaction product, which has been generated by the radicals that do not contribute to the surface reaction on the substrate and can adhere to (can be generated in) the place where it is difficult to remove the deposit by the dry cleaning, when the film formation is performed by the PEALD will be described with reference to the accompanying drawings. Further, in the present specification and the drawings, substantially the same components will be denoted by the same reference numerals and redundant descriptions thereof will be omitted.

### First Exemplary Embodiment

FIG. 1 is a longitudinal cross-sectional view schematically illustrating a configuration of a plasma processing apparatus as the film forming apparatus according to a first exemplary embodiment. Further, in the present exemplary embodiment, a plasma processing apparatus 1 will be described as, for example, a capacitively coupled plasma processing apparatus capable of performing both a film formation and an etching. Furthermore, the plasma processing apparatus 1 is configured to form a SiO₂ film with O radicals.

As illustrated in FIG. 1, the plasma processing apparatus 1 includes an approximately cylindrical processing container 10. In the processing container 10, plasma is formed and a semiconductor wafer (hereinafter, referred to as “wafer”) W serving as the substrate is airtightly accommodated. In the present exemplary embodiment, the processing container 10 is configured to process a wafer W having a diameter of 300 mm. The processing container 10 is formed of, for example, aluminum, and anodic oxidation is performed on the inner wall surface thereof. This processing container 10 is frame-grounded.

A placing table 11 on which the wafer W is placed is accommodated within the processing container 10.

The placing table 11 includes an electrostatic chuck 12 and an electrostatic chuck placing plate 13. The electrostatic chuck 12 includes a placing member 12a on an upper side thereof and a base member 12b on a lower side thereof. The electrostatic chuck placing plate 13 is provided under the base member 12b of the electrostatic chuck 12. Also, the base member 12b and the electrostatic chuck placing plate 13 are formed of a conductive material such as metal, for example, aluminum (Al), and function as a lower electrode.

The placing member 12a has a structure in which an electrode is provided between a pair of insulating layers. The electrode is connected to a DC power supply 21 via a switch 20. Further, the wafer W is attracted onto a placing surface of the placing member 12a by an electrostatic force which is generated when a DC voltage is applied to the electrode from the DC power supply 21.

Further, a coolant flow path 14a is formed within the base member 12b. A coolant is supplied into the coolant flow path 14a from a chiller unit (not illustrated) provided outside the processing container 10 through a coolant inlet line 14b. The coolant supplied into the coolant flow path 14a returns back to the chiller unit through a coolant outlet line 14c. As such, the coolant, for example, cooling water is circulated in the coolant flow path 14a, so that the placing table 11 and the wafer W placed on the placing table 11 can be cooled to a predetermined temperature.

Furthermore, a heater 14d serving as a heating device is provided above the coolant flow path 14a of the base member 12b. The heater 14d is connected to a heater power supply 22, and when a voltage is applied from the heater power supply 22, the placing table 11 and the wafer W placed on the placing table 11 can be heated to a predetermined temperature. Also, the heater 14d may be provided in the placing member 12a.

Besides, a gas flow path 14e through which a cold heat transfer gas (backside gas), such as a helium gas or the like, is supplied to a rear surface of the wafer W from a gas source (not illustrated) is provided in the placing table 11. The wafer W attracted and held on the placing surface of the placing table 11 by the electrostatic chuck 12 can be controlled to a predetermined temperature by using the cold heat transfer gas.

The placing table 11 configured as described above is supported on an approximately cylindrical support member 15 provided on a bottom portion of the processing container 10. The support member 15 is formed of an insulator, for example, ceramics and the like.

An annular focus ring 16 may be provided on a peripheral portion of the base member 12b of the electrostatic chuck 12 to surround the side of the placing member 12a. The focus ring 16 is provided coaxially with respect to the electrostatic chuck 12. The focus ring 16 is provided to improve the uniformity in plasma processing. Also, the focus ring 16 is formed of a material appropriately selected depending on the plasma processing such as etching, and may be formed of, for example, silicon or quartz.

Above the placing table 11, a shower head 30 serving as a plasma source is provided to face the placing table 11. The shower head 30 functions as an upper electrode and includes an electrode plate 31 disposed to face the wafer W on the placing table 11 and an electrode support 32 provided on the electrode plate 31. Further, the shower head 30 is supported on an upper portion of the processing container 10 with an insulating shield member 33 therebetween.

The electrode plate 31 and the electrostatic chuck placing plate 13 function as a pair of electrodes (upper electrode and lower electrode). A plurality of gas discharge holes 31a is formed in the electrode plate 31. The gas discharge holes 31a are configured to supply a processing gas into a processing space S located above the placing table 11 within the processing container 10. Further, the electrode plate 31 is formed of, for example, silicon (Si).

The electrode support 32 is configured to support the electrode plate 31 in a detachable manner, and is formed of a conductive material, for example, aluminum having an anodically oxidized surface. A gas diffusion space 32a is formed within the electrode support 32. A plurality of gas flow holes 32b communicating with the gas discharge holes 31a are formed from the gas diffusion space 32a. Further, the electrode support 32 is connected to a gas source group 40 via a flow rate controller group 41, a valve group 42, a gas supply line 43 and a gas inlet opening 32c to supply the processing gas into the gas diffusion space 32a.

The gas source group 40 has a plurality of gas sources for gases required for the plasma processing. In the plasma processing apparatus 1, a processing gas from one or more gas sources selected from the gas source group 40 is supplied into the gas diffusion space 32a via the flow rate controller 41, the valve group 42, the gas supply line 43 and the gas inlet opening 32c. Further, the processing gas supplied into the gas diffusion space 32a is introduced in a shower shape to be supplied into the processing space S through the gas flow holes 32b and the gas discharge holes 31a.

To supply the processing gas into the processing space S within the processing container 10 without using the shower head 30, a gas inlet hole 10a is formed at a side wall of the processing container 10. The number of gas inlet holes 10a may be one, or two or more. The gas inlet hole 10a is connected to the gas source group 40 via a flow rate controller group 44, a valve group 45 and a gas supply line 46.

Also, a carry-in/out opening 10b for the wafer W is formed at the side wall of the processing container 10 and can be opened or closed by a gate valve 10c.

Further, a deposit shield (hereinafter, referred to as “shield”) 50 is detachably provided on the side wall of the processing container 10 along an inner peripheral surface thereof. The shield 50 is configured to suppress adhesion of a deposit or an etching by-product, which is generated during the film formation, to the inner wall of the processing container 10, and may be formed of, for example, aluminum coated with ceramic such as Y₂O₃. Furthermore, a deposit shield (hereinafter, referred to as “shield”) 51, which is identical to the shield 50, is detachably provided on an outer circumference surface of the support member 15 to face the shield 50.

An exhaust opening 52 for exhausting the inside of the processing container 10 is formed at the bottom portion of the processing container 10. The exhaust opening 52 is connected to an exhaust device 53, for example, a vacuum pump, and the exhaust device 53 is configured to depressurize the inside of the processing container 10.

Further, the processing container 10 includes therein an exhaust path 54 that connects the above-described processing space S and the exhaust opening 52. The exhaust path 54 is partitioned by an inner circumference surface of the side wall of the processing container 10 including an inner circumference surface of the shield 50 and the outer peripheral surface of the support member 15 including an outer peripheral surface of the shield 51. A gas within the processing space S is exhausted to the outside of the processing container 10 via the exhaust path 54 and the exhaust opening 52.

A flat exhaust plate 54a is provided at an end portion on the exhaust opening 52 side of the exhaust path 54, i.e., at an end portion at an exhaust-direction downstream side, to block the exhaust path 54. Herein, the exhaust plate 54a includes through-holes and thus does not interrupt the exhaust flow within the processing container 10 via the exhaust path 54 and the exhaust opening 52. The exhaust plate 54a is formed of, for example, aluminum coated with ceramic such as Y₂O₃.

Further, the plasma processing apparatus 1 is connected to a first radio frequency power supply 23a and a second radio frequency power supply 23b via a first matching device 24a and a second matching device 24b, respectively.

The first radio frequency power supply 23a is configured to generate a radio frequency power for plasma formation having an effective power of less than 500 W to supply the radio frequency power to the shower head 30 under the control of a controller 100 which will be described later. The first radio frequency power supply 23a of the present exemplary embodiment supplies a continuously oscillating radio frequency power equal to or larger than 50 W and smaller than 500 W to the electrode support 32 of the shower head 30. A frequency of the radio frequency power from the first radio frequency power supply 23a is, for example, 27 MHz to 100 MHz. The first matching device 24a has a circuit configured to match an output impedance of the first radio frequency power supply 23a with an input impedance of a load side (the electrode support 32 side).

The second radio frequency power supply 23b is configured to generate a radio frequency power (radio frequency bias power) for ion attraction into the wafer W to supply the radio frequency bias power to the electrostatic chuck placing plate 13. A frequency of the radio frequency bias power is in the range of 400 kHz to 13.56 MHz, for example, 3 MHz. The second matching device 24b has a circuit configured to match an output impedance of the second radio frequency power supply 23b and an input impedance of a load side (the electrostatic chuck placing plate 13 side).

The above-described plasma processing apparatus 1 is equipped with the controller 100. The controller 100 is, for example, a computer and includes a program storage (not illustrated). The program storage stores programs which control processings of the wafer W in the plasma processing apparatus 1. Further, the program storage stores control programs for controlling various processings to be controlled by a processor, or programs, i.e., processing recipes, for operating the respective components of the plasma processing apparatus 1 to execute processings based on processing conditions. Furthermore, the programs may be recorded in a computer-readable recording medium and then installed from the recording medium to the controller 100.

Hereinafter, a processing on the wafer W in the plasma processing apparatus 1 configured as described above will be described with reference to FIG. 2.

(Process S1)

First, as illustrated in FIG. 2, the wafer W is carried in the processing container 10. Specifically, in a state where the inside of the processing container 10 is exhausted to a vacuum atmosphere of a predetermined pressure, the gate valve 10c is opened, and the wafer W is transferred from a transfer chamber, which is in a vacuum atmosphere and adjacent to the processing container 10, onto the placing table 11 by a transfer mechanism. After the wafer W is transferred to the placing table 11 and the transfer mechanism is retreated from the processing container 10, the gate valve 10c is closed.

(Process S2)

Then, a reaction precursor containing Si is formed on the wafer W. Specifically, an Si source gas is supplied into the processing container 10 from a gas source selected from the plurality of gas sources of the gas source group 40 through the gas inlet hole 10a. Thus, an adsorption layer formed of the reaction precursor containing Si is formed on the wafer W. Further, the pressure within the processing container 10 is adjusted to a predetermined level by operating the exhaust device 53. The Si source gas is, for example, an aminosilane-based gas.

(Process S3)

Then, the space within the processing container 10 is purged. Specifically, the Si source gas in a gas phase is exhausted from the processing container 10. During the exhaustion, a rare gas, such as Ar gas, or an inert gas, such as nitrogen gas, may be supplied as a purge gas into the processing container 10. The process S3 may also be omitted.

(Process S4)

Thereafter, SiO₂ is formed on the wafer W by a plasma processing. Specifically, an O containing gas is supplied into the processing container 10 from a gas source selected from the plurality of gas sources of the gas source group 40 through the shower head 30. Further, the continuously oscillating radio frequency power equal to or larger than 50 W and smaller than 500 W is supplied from the first radio frequency power supply 23a. Furthermore, the pressure within the processing container 10 is adjusted to a predetermined level by operating the exhaust device 53. Thus, plasma is formed from the O containing gas. Then, O radicals contained in the generated plasma modify the Si precursor formed on the wafer W. Specifically, the above-described precursor contains a bond of Si and H, and, thus, H of the precursor is substituted with O by the O radicals. Therefore, SiO₂ is formed on the wafer W. The O containing gas is, for example, a carbon dioxide (CO₂) gas or an oxygen (O₂) gas.

The modification of the wafer W (precursor) with the O radicals is performed for a predetermined time period or more. The predetermined time period is previously determined depending on the magnitude of radio frequency power.

(Process S5)

Then, the space within the processing container 10 is purged. Specifically, the O containing gas is exhausted from the processing container 10. During the exhaustion, a rare gas, such as Ar gas, or an inert gas, such as nitrogen gas, may be supplied as a purge gas into the processing container 10. The process S5 may also be omitted.

By performing the cycle of the above-described processes S2 to S5 one or more times, an atomic layer of SiO₂ is deposited on the surface of the wafer W to form a SiO₂ film. Further, the number of times of performing the cycle is set depending on a desired film thickness of the SiO₂ film.

In the present exemplary embodiment, during the process S4, the continuously oscillating radio frequency power equal to or larger than 50 W and smaller than 500 W is supplied as the radio frequency power for plasma formation. The present inventors have found that when the magnitude of the continuously oscillating radio frequency power is set in the range equal to or larger than 50 W and smaller than 500 W during the process S4, the adhesion amount of the deposit in the place where it is difficult to remove the deposit by the dry cleaning can be reduced without reducing the film formation property of SiO₂. Here, the “place where it is difficult to remove the deposit by the dry cleaning” refers to a portion at the exhaust-direction downstream side than the exhaust plate 54a. Further, the “film formation property” refers to the thickness and in-plane uniformity of the film formed within a predetermined time period.

(Process S6)

When the cycle of the above-described processes S2 to S5 is ended, it is determined whether a stop condition for the cycle is satisfied. Specifically, for example, it is determined whether the cycle is performed a predetermined number of times.

If the stop condition is not satisfied (if NO), the cycle of the processes S2 to S5 is performed again.

(Process S7)

If the stop condition is satisfied (if Yes), i.e., if the film formation is ended, a desired processing, such as etching on an etching target layer with the obtained SiO₂ film as a mask, is performed within the same processing container 10. The process S7 may also be omitted.

In the present exemplary embodiment, the etching is consecutively performed within the processing container 10 after the film formation. However, the film formation may be performed after the etching or between the etching and the etching.

(Process S8)

Then, the wafer W is carried out from the processing container 10 in reverse order from which the wafer W is carried into the processing container 10. Thus, the processing in the plasma processing apparatus 1 is ended.

Also, after the above-described processing is performed on a predetermined number of wafers W, a cleaning processing is performed on the plasma processing apparatus 1. Specifically, an F containing gas is supplied into the processing container 10 from a gas source selected from the plurality of gas sources of the gas source group 40. Further, the radio frequency power is supplied from the first radio frequency power supply 23a. Furthermore, the pressure of the space within the processing container 10 is adjusted to a predetermined level by operating the exhaust device 53. Thus, plasma is formed from the F element containing gas. Then, F radicals contained in the generated plasma decompose and remove the deposit derived from the O radicals adhering to the inside of the processing container 10. Further, even when the deposit adheres to the portion at the exhaust-direction downstream side than the processing container 10 during the cleaning, if the amount of the deposit is small, the deposit can be decomposed and removed by the F radicals. The decomposed deposit is discharged by the exhaust device 53.

Also, the above-described F containing gas is, for example, a CF₄ gas, an SF₆ gas, an NF₃ gas, or the like. The cleaning gas contains these F containing gases and may further contain an O containing gas, such as O₂ gas, or an Ar gas, if necessary. Further, during the cleaning, the pressure within the processing container 10 is in the range of one hundred to several hundred mTorr.

According to the present exemplary embodiment, when SiO₂ is formed by forming the plasma of the O containing gas and modifying the surface of the wafer W with the O radicals contained in the plasma, the continuously oscillating radio frequency power equal to or larger than 50 W and smaller than 500 W is supplied from the first radio frequency power supply 23a. Therefore, it is possible to reduce the adhesion amount of the deposit generated by the reaction between the O radicals and the adsorption layer formed of the precursor, specifically, in the portion at the exhaust-direction downstream side than the exhaust plate 54a. The deposit, if any, is small in amount and can be removed in a short time by the simple dry cleaning. Therefore, it is possible to improve the productivity.

Also, a mechanism for reducing the adhesion amount of the deposit by setting the magnitude of the continuously oscillating radio frequency power supplied from the first radio frequency power supply 23a in the range equal to or larger than 50 W and smaller than 500 W is assumed as follows.

If the magnitude of the continuously oscillating radio frequency power is in the range equal to or larger than 50 W to and smaller than 500 W, the amount of the O radicals generated in the processing space S is sufficient for the reaction precursor on the entire surface of the wafer W to react, but is smaller than in the case where the magnitude of the continuously oscillating radio frequency power is, for example, 1000 W or more. Therefore, the amount of the O radicals that do not contribute to the surface reaction on the wafer W and are not deactivated within the processing space S and the exhaust path 54 decreases. As a result, it is assumed that the adhesion amount of the deposit derived from the O radicals, particularly, the amount of the unnecessary deposit in the portion at the exhaust-direction downstream side than the exhaust plate 54a can be reduced.

Also, in the method according to the present exemplary embodiment, it is possible to reduce the adhesion amount of the deposit in a wide area including the whole inside of the processing container 10 and the whole portion at the exhaust-direction downstream side than the exhaust plate 54a.

(Evaluation Test 1)

The present inventors conduct a test on the amounts of the deposit adhering to test pieces by attaching the test pieces to portions P1 to P4 as shown in FIG. 3 and repeating the cycle of the above-described processes S2 to S5 500 times or 600 times. The portion P1 refers to a portion between the side wall of the processing container 10 and the shield 50 and higher in height than the wafer W on the placing table 11. Also, the portion P2 the portion P1 refers to a portion between the side wall of the processing container 10 and the shield 50 and approximately equal in height to the wafer W on the placing table 11. The portion P3 refers to a portion between the side wall of the processing container 10 and the shield 50 and lower in height than the wafer W on the placing table 11. The portion P4 refers to a portion at the downstream side than the exhaust plate 54a and is the lowermost portion of a manifold closest to the exhaust plate 54a.

In this evaluation test, the present inventors measure the amounts of the deposit at different magnitudes of the continuously oscillating radio radio frequency power when the plasma of the O radicals is formed.

FIG. 4 shows the result of the evaluation test 1 and shows the amounts of the deposit when the plasma of the O radicals is formed under processing conditions 1-1 to 1-4, respectively.

Under the processing conditions 1-1, 1-2, 1-3 and 1-4, the magnitudes of the continuously oscillating radio frequency power are 1000 W, 400 W, 250 W and 150 W, respectively. Also, under the processing conditions 1-1 to 103, the cycle of the above-described processes S2 to S5 is repeated 500 times, and under the processing condition 1-4, the cycle is repeated 600 times.

In the evaluation test 1, under the processing condition 1-1, i.e., when the magnitude of the continuously oscillating radio frequency power is 1000 W, the amount of the deposit is large, over 80 nm, in all of the portions P1 to P4 as shown in FIG. 4. However, it has been found that under the processing conditions 1-2 to 1-4, i.e., when the magnitudes of the continuously oscillating radio frequency power are 400 W, 250 W and 150 W, respectively, the amounts of the deposit decrease in all of the portions P1 to P4 compared with 1000 W. Also, it has been found that as the continuously oscillating radio frequency power decreases, the amounts of the deposit decrease.

Further, when the magnitude of the continuously oscillating radio frequency power is 50 W or more, the in-plane uniformity of SiO₂ obtained from the evaluation test 1 is hardly changed depending on the magnitude of the power.

Plasma etching is performed to the SiO₂ film formed using the continuously oscillating radio radio frequency power in the same manner as in the evaluation test 1. Etching conditions are as follows.

Pressure within processing chamber: 40 mTorr

Radio frequency power for plasma formation: 300 W

Radio frequency bias power: 100 W

Gas flow rate: CF₄/Ar=500 sccm/40 sccm

Etching time: 15 seconds

According to the result, there is no difference in the etching amount and the in-plane uniformity in etching amount even when the magnitude of the continuously oscillating radio frequency power is changed. Specifically, when the magnitudes of the continuously oscillating radio frequency power are 400 W and 250 W, the averages of the etching amounts are 22.5 nm and 22.6 nm, respectively, and the in-plane non-uniformity in etching amount is ±3.5% from the average in each case. That is, it is found that even if the magnitude of the continuously oscillating radio frequency power is changed as the countermeasure against the deposit, there is no problem associated with practical use.

### Second Exemplary Embodiment

The plasma processing apparatus 1 according to a second exemplary embodiment is different from the plasma processing apparatus 1 according to the first exemplary embodiment only in a radio frequency power supply for plasma formation.

In the present exemplary embodiment, the first radio frequency power supply 23a configured to supply the radio frequency power for plasma formation having the effective power smaller than 500 W may supply a pulse-shaped power in which a period with the power of an ON level and a period with the power of an OFF level are alternated periodically. Also, the OFF level of the pulse-shaped power may not be zero. That is, the first radio frequency power supply 23a may also generate the pulse-shaped power in which a period with the power of a high level and a period with the power of a low level are alternated periodically.

In the present exemplary embodiment, the first radio frequency power supply 23a supplies the radio frequency power which is of the pulse wave shape having a duty ratio of 75% or less and a frequency of 5 kHz or more and which has an effective power smaller than 500 W when performing pulse modulation. More specifically, in the present exemplary embodiment, the first radio frequency power supply 23a supplies the radio frequency power which is of the pulse wave shape having the duty ratio smaller than 50% and the frequency ranging from 5 kHz to 20 kHz and which has the magnitude in the range of 150 W to 300 W. Further, the effective power when performing the pulse modulation is the magnitude of the radio frequency power multiplied by the duty ratio. For example, if the magnitude of the radio frequency power supplied in the form of the pulse wave is 1000 W and the duty ratio is 30%, the effective power is 300 W.

In the present exemplary embodiment, when SiO₂ is formed by modifying the surface of the wafer W using the O radicals contained in the plasma in the process S4, the radio frequency power, which is of the pulse wave having the duty ratio of 75% or less and the frequency of 5 kHz or more and which has the effective power of less than 500 W, is supplied. The present inventors have found that when the radio frequency power is supplied in the form of the pulse wave, the adhesion amount of the deposit in the place where it is difficult to remove the deposit by the dry cleaning can be reduced without reducing the film formation property of SiO. Also, the present inventors have found that when the radio frequency power equal in magnitude to the radio frequency power used in the first exemplary embodiment is used in the present exemplary embodiment, the adhesion amount of the deposit in the place where it is difficult to remove the deposit by the dry cleaning can be further reduced compared with the first exemplary embodiment.

Also, a mechanism for reducing the adhesion amount of the deposit in the place where it is difficult to remove the deposit by the dry cleaning is assumed as follows.

If the radio frequency power, which is of the pulse wave having the duty ratio smaller than 75% and the frequency of 5 kHz or more and which has the effective power smaller than 500 W, is supplied, the amount of the O radicals generated in the processing space S is sufficient for the reaction precursor on the entire surface of the wafer W to react, but is smaller than in the case where the continuously oscillating radio frequency power having the equivalent magnitude is supplied. Therefore, the amount of the O radicals that do not contribute to the surface reaction on the wafer W and are not deactivated within the processing space S and the exhaust path 54 further decreases. As a result, it is assumed that the adhesion amount of the deposit derived from the O radicals particularly in the portion, such as the place at the exhaust-direction downstream side than the exhaust plate 54a, where it is difficult to remove the deposit by the dry cleaning can be reduced.

(Evaluation Test 2)

The present inventors conduct a test on the amounts of the deposit adhering to test pieces by attaching the test pieces to the portions P1 to P4 as shown in FIG. 3 and repeating the cycle of the above-described processes S2 to S5 500 times.

In this evaluation test, the present inventors measure the amounts of the deposit under the pressure within the processing container 10 of 200 mTorr and at different frequencies of the pulse wave of the radio frequency power supplied in the process S4.

FIG. 5 shows the result of the evaluation test 2 and shows the amounts of the deposit when the plasma of the O radicals is formed under processing conditions 2-1 to 2-5, respectively.

Under the processing conditions 2-1, 2-2, 2-3, 2-4 and 2-5, the frequencies of the pulse wave of the radio frequency power are 5 kHz, 10 kHz, 20 kHz, 30 kHz and 50 kHz, respectively. Also, under the processing conditions 2-1 to 2-5, the magnitude of the radio frequency power, the duty ratio of the pulse wave, and the time (process time) required for the process S4 are common and 200 W, 50% and 4 seconds, respectively. Further, under the processing conditions 2-1 to 2-5, the flow rate of CO₂ gas and the flow rate of Ar gas are also common and 290 sccm and 40 sccm, respectively.

In the evaluation test 2, under the processing condition 2-1, i.e., when the frequency of the pulse wave is 5 kHz, the amounts of the deposit are less than 80 nm and 65 nm or less in all of the portions P1 to P4 as shown in FIG. 5. That is, when the radio frequency power having the magnitude of 200 W is supplied in the form of the pulse wave, the amounts of the deposit in all of the portions P1 to P4 decrease by about 20% or more compared with the processing condition 1-1 shown in FIG. 4, i.e., when the continuously oscillating radio frequency power of 1000 W is supplied. The same is applied to the processing conditions 2-2 to 2-5, and the amounts of the deposit decrease by up to 99%.

Further, the film thickness and the in-plane uniformity of SiO₂ obtained from the evaluation test 2 under the processing conditions 2-1 to 2-5 are not much different from those obtained when the SiO₂ film is formed by forming the plasma with the continuously oscillating radio frequency power of 600 W. Specifically, for example, when the magnitude of the radio frequency power is changed to 300 W under the processing condition 2-3, the average of the film thicknesses of the SiO₂ film is 4.0 nm and the in-plane uniformity in film thickness is ±2.7% on average. Meanwhile, when the SiO₂ film is formed with the continuously oscillating radio frequency power of 600 W under the processing condition 2-3 except for only the radio frequency power for plasma formation, the average of the film thicknesses of the SiO₂ film is 4.3 nm and the in-plane uniformity in the film thickness is ±2.6% on average. That is, even when the radio frequency power of a lower magnitude is supplied in the form of the pulse wave to form the plasma, the uniformity of the SiO₂ film is not greatly affected and the film thickness thereof slightly decreases compared with the case where the continuously oscillating radio frequency power is supplied. However, the film thickness can be adjusted by adjusting the number of cycles.

Furthermore, when the SiO₂ film is formed under the processing condition 2-2 except for only the process time that is changed to 2 seconds, the average of the film thicknesses was 3.57 nm and the in-plane uniformity in the film thickness was ±4.4% on average.

Plasma etching is performed on the SiO₂ film formed with the radio frequency power in the form of the pulse wave in the same manner as in the evaluation test 2. Etching conditions are as follows.

Pressure within processing chamber: 40 mTorr

Radio frequency power for plasma formation: 300 W

Radio frequency bias power: 100 W

Gas flow rate: CF₄/Ar=500 sccm/40 sccm

Etching time: 15 seconds

According to the result, there is no difference in the etching amount and the in-plane uniformity in etching amount even when the frequency of the radio frequency power supplied in the form of the pulse wave is changed. For example, when the magnitude of the radio frequency power, the duty ratio, and the process time are common with those of the processing condition 2-1 and the frequencies of the pulse wave are 10 kHz (processing condition 2-2) and 20 kHz (processing condition 2-3), the average of the etching amounts is 22.3 nm in each case. Also, the in-plane non-uniformity in etching amount is ±3.2% from the average in case of 10 kHz (processing condition 2-2) and ±3.6% from the average in case of 20 kHz (processing condition 2-3). That is, it is found that even if the magnitude of the pulse frequency is changed as the countermeasure against the deposit, there is no problem associated with the practical use.

Also, according to the etching result, there is no difference in the etching amount and the in-plane uniformity in etching amount even when the process time is changed. For example, when the film is formed under the same condition as the processing condition 2-2 including the frequency of the pulse wave, the magnitude of the radio frequency power, the duty ratio, and the process time (4 seconds), the average of the etching amounts is 22.3 nm and the in-plane non-uniformity in etching amount is ±3.2% from the average. Even when the film is formed under the same condition except for only the process time that is changed to 8 seconds, the average of the etching amounts and the in-plane uniformity in etching amount are not changed. Also, even when the film is formed under the same condition except for only the process time that is changed to 2 seconds, the average and the like are hardly changed. Further, when the process time is set to 2 seconds, the average of the etching amounts is 22.0 nm and the in-plane non-uniformity in etching amount is ±4.0% from the average.

In the above-described exemplary embodiments, the plasma processing apparatus 1 performs the film formation and the etching after the film formation. However, the plasma processing apparatus 1 may perform the etching before the film formation and perform the film formation during the etching. Otherwise, the plasma processing apparatus 1 may perform the etching both before and after the film formation or may perform only the film formation without the etching.

In the above-described exemplary embodiments, the plasma processing apparatus 1 uses capacitively coupled plasma for the film formation and the etching. However, the plasma processing apparatus 1 may use inductively coupled plasma or surface wave plasma, such as microwave, for the film formation and the etching.

Further, in the above-described exemplary embodiments, the SiO₂ film is formed with the O radicals. However, the above-described exemplary embodiments can also be applied to the film formation with other radicals, such as formation of a SiN film with nitrogen radicals.

It should be understood that the exemplary embodiments disclosed herein are illustrative in all aspects and do not limit the present disclosure. The above-described exemplary embodiments may be omitted, substituted, or changed in various forms without departing from the scope and spirit of the appended claims.

Also, the following configurations also belong to the technical scope of the present disclosure.

(1) A film forming method of forming a predetermined film on a substrate by PEALD, comprising:

adsorbing a precursor on the substrate; and

forming plasma from a modifying gas and modifying the precursor adsorbed on the substrate with radicals contained in the plasma,

wherein the modifying of the precursor includes supplying a radio frequency power having an effective power smaller than 500 W to a plasma source configured to form the plasma from the modifying gas.

(2) The film forming method described in the above (1), wherein, in the supplying of the radio frequency power, a continuously oscillating radio frequency power equal to or larger than 50 W and smaller than 500 W is supplied.

(3) The film forming method described in the above (1), wherein, in the supplying of the radio frequency power, a radio frequency power is supplied in a form of a pulse wave having a duty ratio of 75% or less and a frequency of 5 kHz or more.

(4) The film forming method described in any one of the above (1) to (3), wherein the modifying of the precursor is performed for a predetermined time period or more.

(5) The film forming method described in any one of the above (1) to (4) further comprising removing a reaction product generated in a place than the substrate with the radicals.

(6) A film forming apparatus configured to form a predetermined film on a substrate by PEALD, comprising:

a processing container, in which plasma is formed, configured to airtightly accommodate therein the substrate;

a plasma source configured to form plasma from a modifying gas configured to modify a precursor adsorbed on the substrate within the processing container;

a radio frequency power supply configured to supply a radio frequency power for plasma formation to the plasma source; and

a controller configured to control the radio frequency power supply to supply a radio frequency power having an effective power smaller than 500 W as the radio frequency power for plasma formation to the plasma source.

### EXPLANATION OF CODES

1, 1a: Plasma processing apparatus

10: Processing container

23a: first radio frequency power supply

30: shower head

100: Controller

W: Wafer

1. A film forming method of forming a predetermined film on a substrate by PEALD, comprising:
adsorbing a precursor on the substrate; and
forming plasma from a modifying gas and modifying the precursor adsorbed on the substrate with radicals contained in the plasma,
wherein the modifying of the precursor includes supplying a radio frequency power having an effective power smaller than 500 W to a plasma source configured to form the plasma from the modifying gas.

2. The film forming method of claim 1,
wherein, in the supplying of the radio frequency power, a continuously oscillating radio frequency power equal to or larger than 50 W and smaller than 500 W is supplied.

3. The film forming method of claim 1,
wherein, in the supplying of the radio frequency power, a radio frequency power is supplied in a form of a pulse wave having a duty ratio of 75% or less and a frequency of 5 kHz or more.

4. The film forming method of claim 1,
wherein the modifying of the precursor is performed for a predetermined time period or more.

5. (canceled)

6. (canceled)

7. The film forming method of claim 2,
wherein the modifying of the precursor is performed for a predetermined time period or more.

8. The film forming method of claim 3,
wherein the modifying of the precursor is performed for a predetermined time period or more.

9. The film forming method of claim 1, further comprising:
removing a reaction product generated in a place than the substrate with the radicals.

10. The film forming method of claim 2, further comprising:
removing a reaction product generated in a place than the substrate with the radicals.

11. The film forming method of claim 3, further comprising:
removing a reaction product generated in a place than the substrate with the radicals.

12. The film forming method of claim 4, further comprising:
removing a reaction product generated in a place than the substrate with the radicals.

13. The film forming method of claim 5, further comprising:
removing a reaction product generated in a place than the substrate with the radicals.

14. The film forming method of claim 6, further comprising:
removing a reaction product generated in a place than the substrate with the radicals.

15. The film forming method of claim 1,
wherein the precursor contains Si, and the modifying gas is an O containing gas.

16. The film forming method of claim 11,
wherein the precursor contains Si, and the modifying gas is an O containing gas.

17. The film forming method of claim 12,
wherein the precursor contains Si, and the modifying gas is an O containing gas.

18. A film forming apparatus configured to form a predetermined film on a substrate by PEALD, comprising:
a processing container, in which plasma is formed, configured to airtightly accommodate therein the substrate;
a plasma source configured to form plasma from a modifying gas configured to modify a precursor adsorbed on the substrate within the processing container;
a radio frequency power supply configured to supply a radio frequency power for plasma formation to the plasma source; and
a controller configured to control the radio frequency power supply to supply a radio frequency power having an effective power smaller than 500 W as the radio frequency power for plasma formation to the plasma source.
